(19) United States
(12) Patent Application Publication
(10) Pub. No.: US 2021/0049940 A1
(43) Pub. Date: Feb. 18, 2021

(54) Display

(71) Applicant: Sony Corporation, Tokyo (JP)

(72) Inventors: Yohei AZUMA, Kanagawa (JP); Takeshi YAMAMOTO, Tokyo (JP); Hayato NIWA, Tokyo (JP)

(73) Assignee: Sony Corporation, Tokyo (JP)

(21) Appl. No.: 16/979,987

(22) PCT Filed: Feb. 14, 2019
(86) PCT No.: PCT/JP2019/005227

§ 371 Date: Sep. 11, 2020

(30) Foreign Application Priority Data
Mar. 29, 2018 (JP) 2018-063869

(51) Int. Cl. G09F 9/302; G09F 9/30; G06F 1/16

(52) U.S. Cl. CPC G09F 9/3026; G06F 1/1609; G09F 9/301

(57) ABSTRACT

A display including a first display section (S1), a second display section (S2), and a light guide member (FOP20A). The first display section (P1) has a first display surface (S1) including a first middle region (SC1) and a curved first end region (SL1) and outputting first image light. The second display section (P2) has a second display surface (S2) including a second middle region (SC2) and a curved second end region (SL2) and outputting second image light. The second display surface (S2) is adjacent to the first display section (P1) via a gap (G1). The light guide member (FOP20A) is provided on the gap (G), outputs the first image light from the first end region (SL1) to a first outgoing surface (23A), and outputs the second image light from the second end region (SL2) to a second outgoing surface (23B).

### TECHNICAL FIELD

The present disclosure relates to a display.

### BACKGROUND ART

Proposals have been previously made for a large multi-display in which a plurality of display panels is arranged (for example, refer to Patent Literature 1).

### CITATION LIST

### Patent Literature

Patent Literature 1: Japanese Unexamined Patent Application Publication No. 2014-119562

### SUMMARY OF THE INVENTION

In such a multi-display, boundary portions between a plurality of arranged display panels are often visually recognized as dark lines.

Therefore, it is desirable to provide a display that makes it possible to display a good image in which dark lines are less likely to be recognized by a viewer.

A first display according to an embodiment of the present disclosure includes a first display section, a second display section, and a light guide member. The first display section has a first display surface including a first middle region and a curved first end region and outputting first image light. The second display section has a second display surface including a second middle region and a curved second end region and outputting second image light. The second display surface is adjacent to the first display section via a gap. The light guide member is provided on the gap and has a first entering surface where the first image light from the first end region of the first display surface enters, a first outgoing surface that outputs the first image light from the first entering surface, a second entering surface where the second image light from the second end region of the second display surface enters, and a second outgoing surface that outputs the second image light from the second entering surface.

A second display according to an embodiment of the present disclosure includes a first display section, a second display section, and an optical film. The first display section has a first display surface including a first middle region and a curved first end region and outputting first image light. The second display section has a second display surface including a second middle region and a curved second end region and outputting second image light. The second display surface is adjacent to the first display surface via a gap. The optical film is provided to cover, over the gap, both the first middle region of the first display surface and the second middle region of the second display surface.

The display according to the embodiment of the present disclosure makes it possible to display a good image in which dark lines are less likely to be recognized by a viewer.

Note that effects of the present disclosure are not limited to the effects described above, and may include any of effects described below.

### BRIEF DESCRIPTION OF DRAWING

FIG. 1A is a front view of an example of a whole configuration of a display according to a first embodiment of the present disclosure.

FIG. 1B is a cross-sectional view of a configuration of the display illustrated in FIG. 1A.

FIG. 1C is an enlarged cross-sectional view of a principal part of the display illustrated in FIG. 1A.

FIG. 1D is an enlarged cross-sectional view of a principal part of a fiber optical plate illustrated in FIG. 1A.

FIG. 2A is an enlarged cross-sectional view of a principal part of a display according to a second embodiment of the present disclosure.

FIG. 2B is an enlarged cross-sectional view of a principal part of a first modification example of the display illustrated in FIG. 2A.

FIG. 2C is an enlarged cross-sectional view of a principal part of a second modification example of the display illustrated in FIG. 2A.

FIG. 3A is an enlarged cross-sectional view of a principal part of a display according to a third modification example of the present disclosure.

FIG. 3B is an enlarged cross-sectional view of a principal part of a display according to a fourth modification example of the present disclosure.

FIG. 3C is an enlarged cross-sectional view of a principal part of a display according to a fifth modification example of the present disclosure.

FIG. 4A is an enlarged cross-sectional view of a principal part of a display according to a sixth modification example of the present disclosure.

FIG. 4B is an enlarged cross-sectional view of a principal part of a display according to a seventh modification example of the present disclosure.

FIG. 5 is an enlarged cross-sectional view of a principal part of a display according to an eighth modification example of the present disclosure.

### MODES FOR CARRYING OUT THE INVENTION

In the following, embodiments of the present disclosure are described in detail with reference to the drawings. Note that the description is made in the following order.

### 1. First Embodiment

An example of a display in which a fiber optical plate (FOP) is disposed on curved portions near boundaries between a plurality of flexible display panels

2. Second Embodiment and Modification Examples thereof

An example of a display in which optical films are attached to a front surface of the plurality of flexible display panels and the FOP disposed near the boundaries between the flexible display panels

### 3. Modification Example of Second Embodiment

### 4. Other Modification Examples

### 1. FIRST EMBODIMENT

### [Configuration of Display 1]

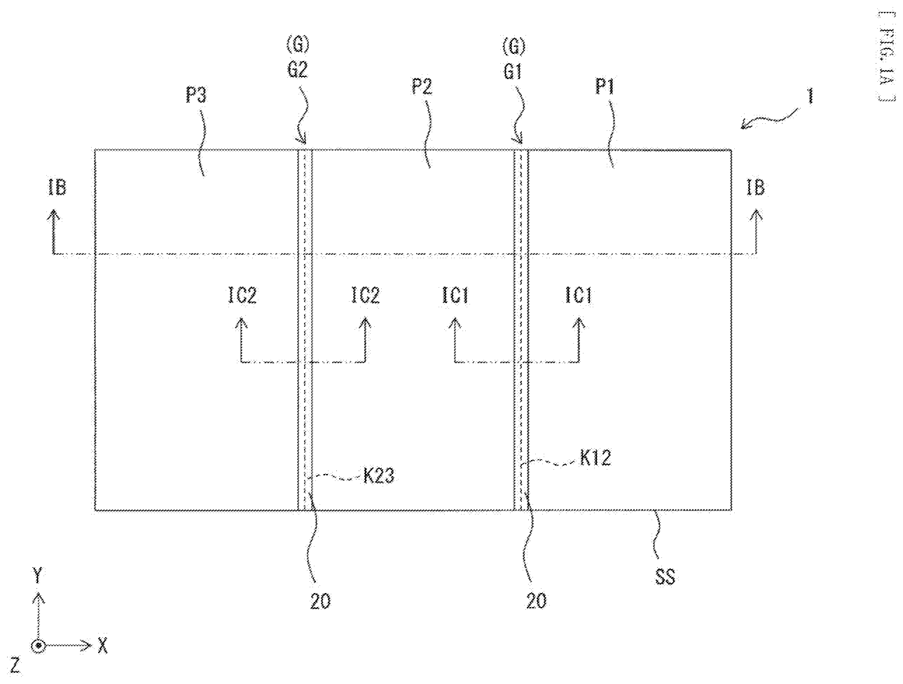

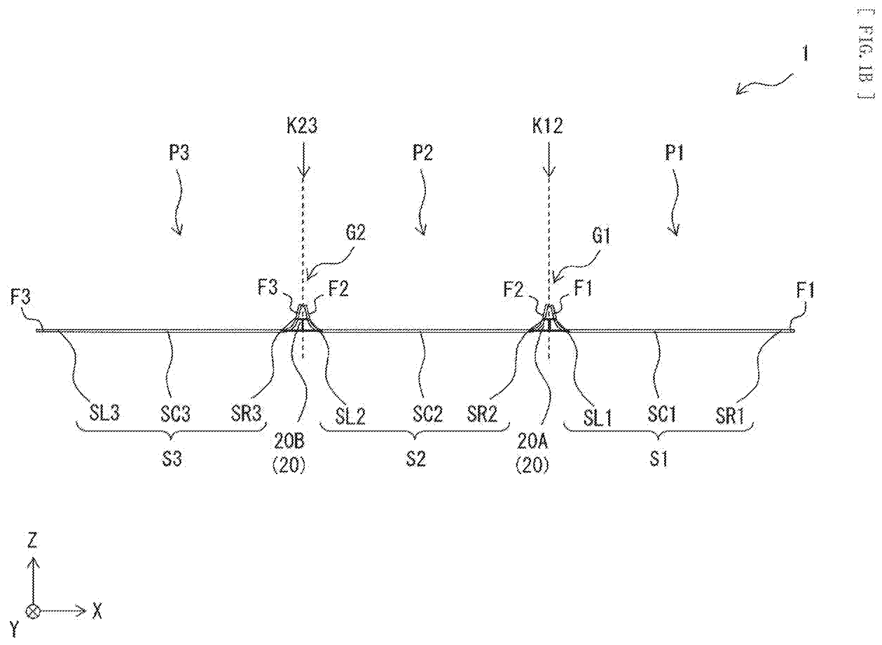

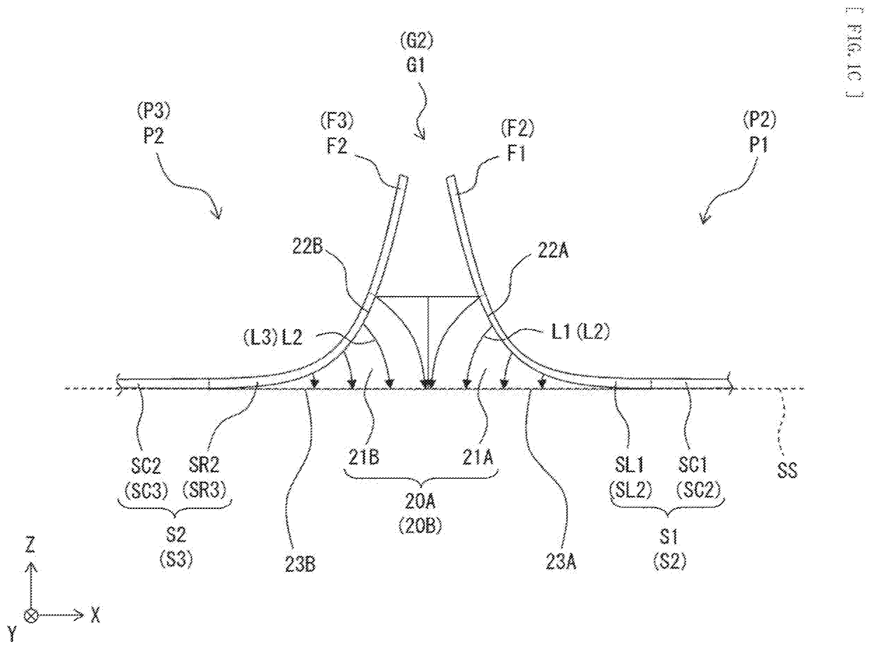

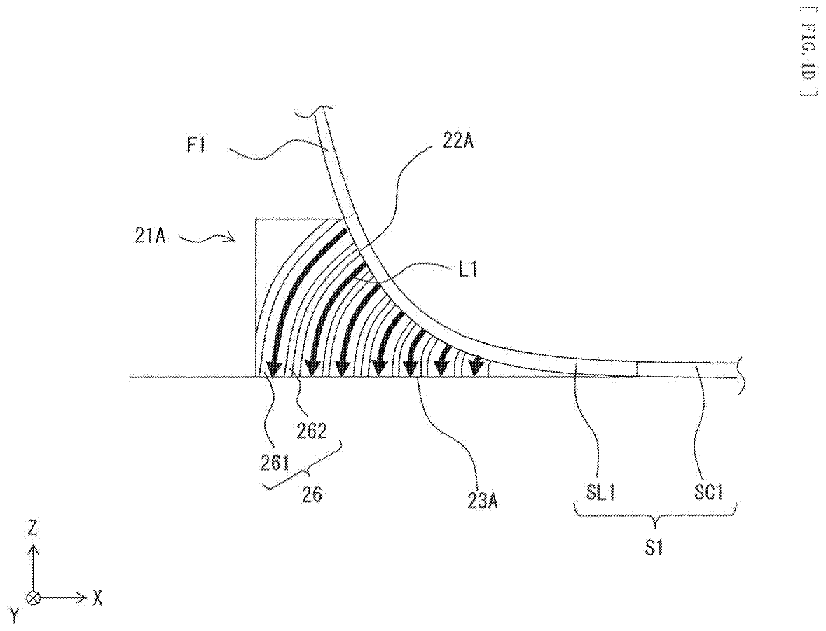

FIGS. 1A and 1B each schematically illustrate an example of the whole configuration of a display 1 according to a first embodiment of the present disclosure. FIG. 1A illustrates a planar configuration of the display 1 and FIG. 1B illustrates a cross-sectional configuration. FIG. 1B corresponds to a cross-sectional view taken along a cutting-plane line IB-IB illustrated in FIG. 1A and as seen in an arrow direction in FIG. 1A. Furthermore, FIG. 1C is an enlarged cross-sectional view of a principal part of the display 1, and corresponds to a cross-sectional view taken along a cutting-plane line IC1-IC1 illustrated in FIG. 1A and as seen in an arrow direction in FIG. 1A, or corresponds to a cross-sectional view taken along a cutting-plane line IC2-IC2 illustrated in FIG. 1A and as seen in an arrow direction in FIG. 1A. In addition, a cross-sectional structure along the cutting-plane line IC1-IC1 in FIG. 1A and a cross-sectional structure along the cutting-plane line IC2-IC2 in FIG. 1A are substantially the same as each other. Note that, regarding components with reference numerals in parentheses, the reference numerals in parentheses represent the components in the cross-sectional structure along the cutting-plane line IC2-IC2 in FIG. 1A.

The display 1 includes a plurality of display panels P1 to P3 coupled and integrated at boundary portions G1 and G2 via fiber optical plates (FOPs) 20. The display panel P1 and the display panel P2 are specific examples that respectively correspond to a “first display member” and a “second display member” of the present disclosure. Furthermore, the boundary portions G1 and G2 are specific examples that correspond to a “gap” of the present disclosure.

Note that, in the present specification, the display panels P1 to P3 may be collectively described as display panels P, and the boundary portions G1 and G2 may be collectively described as boundary portions G. Moreover, in the present embodiment, three display panels P are coupled, but the number is not limited in the present technology.

### [Display Panels P]

The display panels P1 to P3 are so-called flexible displays in a form of a sheet having flexibility. The display panels P1 to P3 are provided with a display device layer including a plurality of pixels using a self-outputting device or a display device. For example, the self-outputting device may be an organic EL (Electro Luminescence) device and the display device may be a liquid crystal device. Each of the display panels P1 to P3 includes display sections S1 to S3 that respectively output pieces of image light L1 to L3, and peripheral parts F1 to F3 that are provided with wiring lines and the like for supplying power to the display sections S1 to S3 and transmitting and receiving signals.

Note that, in the present specification, the pieces of image light L1 to L3 may be collectively described as image light L, the display sections S1 to S3 may be collectively described as display sections S, and the peripheral parts F1 to F3 may be collectively described as peripheral parts F.

The display section S1 includes a pair of end regions SL1 and SR1, and a middle region SC1 that is interposed between the end region SL1 and the end region SR1 in a direction in which the display panels P are arranged, that is, in an X-axis direction. A surface of the middle region SC1 and a surface of the end region SR1 are planes extending in the X-axis direction and a Y-axis direction. On the other hand, a surface of the end region SL1 includes a curved surface that is parallel to the Y-axis direction, but is so curved that a displacement amount in a Z-axis direction increases as a distance from the middle region SC1 increases.

The display section S2 includes a pair of end regions SL2 and SR2, and a middle region SC2 that is interposed between the end region SL2 and the end region SR2 in the X-axis direction. A surface of the middle region SC2 is a plane extending in the X-axis direction and the Y-axis direction. Each surface of the end region SL2 and the end region SR2 includes a curved surface that is parallel to the Y-axis direction, but is so curved that the displacement amount in the Z-axis direction increases as a distance from the middle region SC2 increases.

Similarly, the display section S3 includes a pair of end regions SL3 and SR3, and a middle region SC3 that is interposed between the end region SL3 and the end region SR3 in the X-axis direction. A surface of the middle region SC3 and a surface of the end region SR1 are planes extending in the X-axis direction and the Y-axis direction. On the other hand, a surface of the end region SL3 includes a curved surface that is parallel to the Y-axis direction, but is so curved that the displacement amount in the Z-axis direction increases as a distance from the middle region SC3 increases.

### [FOP 20]

In the display 1, an FOP 20A coupling the display panel P1 and the display panel P2 is disposed at the boundary portion G1, and an FOP 20B coupling the display panel P2 and the display panel P3 is disposed at the boundary portion G2. Each of the FOP 20A and the FOP 20B is a block-shaped optical member in which a plurality of optical fibers 26 (described later) including quartz glass or transparent resin as a main constituent material is bundled and integrated. The FOP 20A and the FOP 20B have substantially the same configuration. The FOP 20A and the FOP 20B propagate the image light L having entered an entering surface to an outgoing surface that is different from the entering surface, and output the image light L. The entering surface is, in other words, a first entering surface 22A and a second entering surface 22B described later. The outgoing surface is, in other words, a first outgoing surface 23A and a second outgoing surface 23B described later.

Note that, in the present specification, the FOP 20A and the FOP 20B may be collectively described as FOPs 20.

As illustrated in FIG. 1C, the FOP 20A includes a first light guide section 21A and a second light guide section 21B that are bonded to each other at a boundary K12. Similarly, the FOP 20B includes the first light guide section 21A and the second light guide section 21B that are bonded to each other at a boundary K23. The first light guide section 21A and the second light guide section 21B may be bonded to each other by bonding with an adhesive such as a transparent resin.

The first light guide section 21A of the FOP 20A has the first entering surface 22A and the first outgoing surface 23A. The first entering surface 22A of the FOP 20A faces the end region SL1, and is a surface where the image light L1 from the end region SL1 enters. The first entering surface 22A of the FOP 20A is curved along the surface of the end region SL1 of the display panel P1. The first entering surface 22A of the FOP 20A is preferably joined to the surface of the end region SL1 of the display panel P1 with a transparent adhesive or the like. The first outgoing surface 23A of the FOP 20A is a surface that outputs the image light L1 having entered the first entering surface 22A to the outside of the first light guide section 21A. Similarly, the first light guide section 21A of the FOP 20B also has the first entering surface 22A and the first outgoing surface 23A. The first entering surface 22A of the FOP 20B faces the end region SL2, and is a surface where the image light L2 from the end region SL2 enters. The first entering surface 22A of the FOP 20B is curved along the surface of the end region SL2 of the display panel P2. The first entering surface 22A of the FOP 20B is preferably joined to the surface of the end region SL2 of the display panel P2 with the transparent adhesive or the like. The first outgoing surface 23A of the FOP 20B is a surface that outputs the image light L2 having entered the first entering surface 22A to the outside of the first light guide section 21A.

The second light guide section 21B of the FOP 20A has the second entering surface 22B and the second outgoing surface 23B. The second entering surface 22B of the FOP 20A is a surface where the image light L2 from the end region SR2 enters. The second entering surface 22B of the FOP 20A faces the end region SR2 of the display panel P2, and is curved along the surface of the end region SR2. The second entering surface 22B of the FOP 20A is preferably joined to the surface of the end region SR2 of the display panel P2 with the transparent adhesive or the like. The second outgoing surface 23B of the FOP 20A is a surface that outputs the image light L2 having entered the second entering surface 22B to the outside of the second light guide section 21B. Similarly, the second light guide section 21B of the FOP 20B also has the second entering surface 22B and the second outgoing surface 23B. The second entering surface 22B of the FOP 20B faces the end region SR3, and is a surface where the image light L3 from the end region SR3 enters. The second entering surface 22B of the FOP 20B is curved along the surface of the end region SR3 of the display panel P3. The second entering surface 22B of the FOP 20B is preferably joined to the surface of the end region SR3 of the display panel P3 with the transparent adhesive or the like. The second outgoing surface 23B of the FOP 20B is a surface that outputs the image light L3 having entered the second entering surface 22B to the outside of the second light guide section 21B.

The surface of the middle region SC1 of the display section S1, the surface of the middle region SC2 of the display section S2, the first outgoing surface 23A and the second outgoing surface 23B of the FOP 20A, the surface of the middle region SC3 of the display section S3, and the first outgoing surface 23A and the second outgoing surface 23B of the FOP 20B integrally form a coupled display surface SS.

FIG. 1D is an enlarged plan view of the first light guide section 21A of the FOP 20A. As illustrated in FIG. 1D, the first light guide section 21A has the plurality of optical fibers 26. Each of the plurality of optical fibers 26 has a core 261 extending from the first entering surface 22A to the first outgoing surface 23A and a cladding 262 surrounding the core 261. A refractive index of the core 261 is higher than a refractive index of the cladding 262. Therefore, the core 261 functions as an optical waveguide that guides the image light L1 having entered the first entering surface 22A to the first outgoing surface 23A. The plurality of optical fibers 26 is curved from the first entering surface 22A to the first outgoing surface 23A to cause, for example, each optical axis to be perpendicular to both the first entering surface 22A and the first outgoing surface 23A. The second light guide section 21B has a configuration substantially line-symmetric with the first light guide section 21A with the boundary K12 as a symmetric axis.

### [Workings and Effects of Display 1]

As described above, because the display 1 according to the present embodiment couples and integrates the plurality of display panels P1 to P3 at the boundary portions G1 and G2, it is possible to form a large display surface as a whole. In particular, because the FOPs 20A and 20B as the light guide members are disposed at the boundary portions G1 and G2, the pieces of image light L1 to L3 outputted from the plurality of display panels P1 to P3 are coupled to each other without any gap. Specifically, as illustrated in FIG. 1C, the first outgoing surface 23A of the first light guide section 21A and the second outgoing surface 23B of the second light guide section 21B of the FOP 20A are adjacent without any gap at the boundary K12. Therefore, the FOP 20A displays the image light L1 from the end region SL1 and the image light L2 from the end region SR2 to cause them to be adjacent to each other. Similarly, the first outgoing surface 23A of the first light guide section 21A and the second outgoing surface 23B of the second light guide section 21B of the FOP 20B are adjacent to each other without any gap at the boundary K23. Therefore, the FOP 20B displays the image light L2 from the end region SL2 and the image light L3 from the end region SR3 to cause them to be adjacent to each other. As described above, an image forming apparatus 100 forms the coupled display surface SS that is single and rectangular as a whole. As a result, it is possible to form an image display surface having larger display area, which makes it difficult for a viewer to recognize joints. Thus, it is possible to provide the viewer with an image which is larger and also excellent in aesthetic quality.

Furthermore, the present embodiment includes the FOP 20 as the light guide member. Because it is possible to transmit a display image on the display section for each region of a pixel size level by the FOP 20, it is possible to provide an image with better image quality to the viewer. On the other hand, a distance from a viewable display surface (viewing distance) is limited if a lens array in which microlenses are arranged, a Fresnel lens, or the like, for example, is used. One reason for this is that an image failure can occur depending on the distance from the display surface (viewing distance). In addition, if the lens array, the Fresnel lens, or the like is used, when viewed from an angle inclined from a direction perpendicular to the display surface, the image quality of the viewed image can be degraded. However, in the case of the FOP, such deterioration in image quality is less likely to occur.

Moreover, because the present embodiment uses a so-called flexible display in a form of a sheet having flexibility as the display panels P, after the display 1 is manufactured in a factory, it is possible to ship and transport the entire display 1 in a wound state. For this reason, the whole dimension at the time of transportation is reduced, allowing for the excellent transportation performance. Furthermore, because the plurality of display panels P is tiled at predetermined positions in the manufacturing stage in the factory and the plurality of display panels P is coupled to each other, it is possible to perform various adjustments such as brightness adjustment and color unevenness adjustment between the plurality of display panels P before shipment, making it possible to improve the display quality of the entire display 1. Therefore, it is possible to simplify or omit adjustment work of the image quality at a place of installation.

### 2. SECOND EMBODIMENT

### [Configuration of Display 2A]

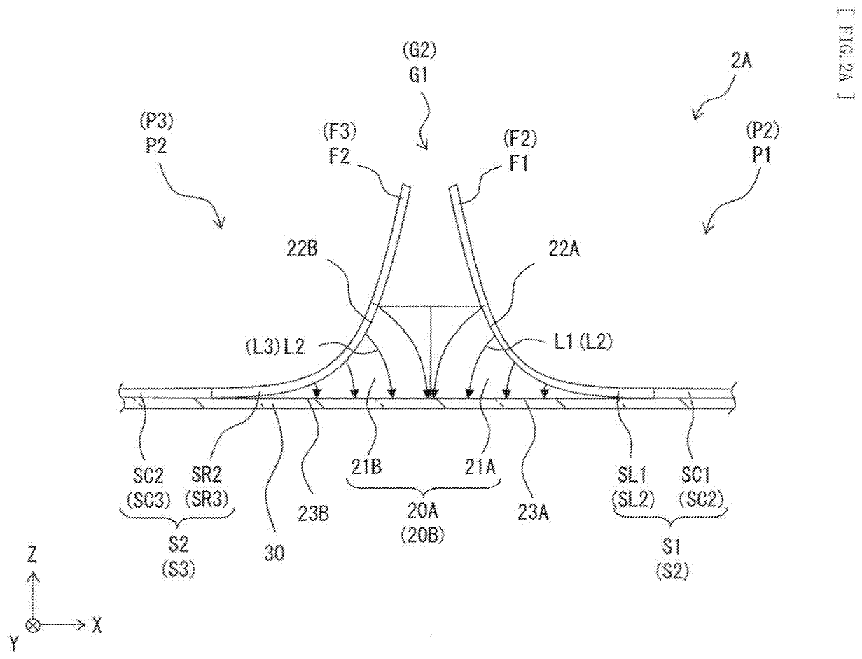

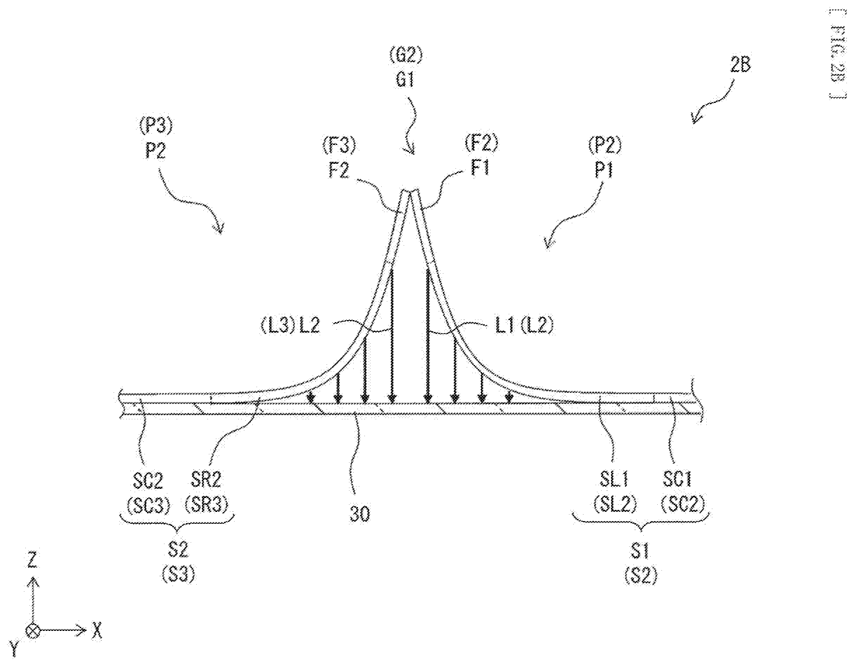

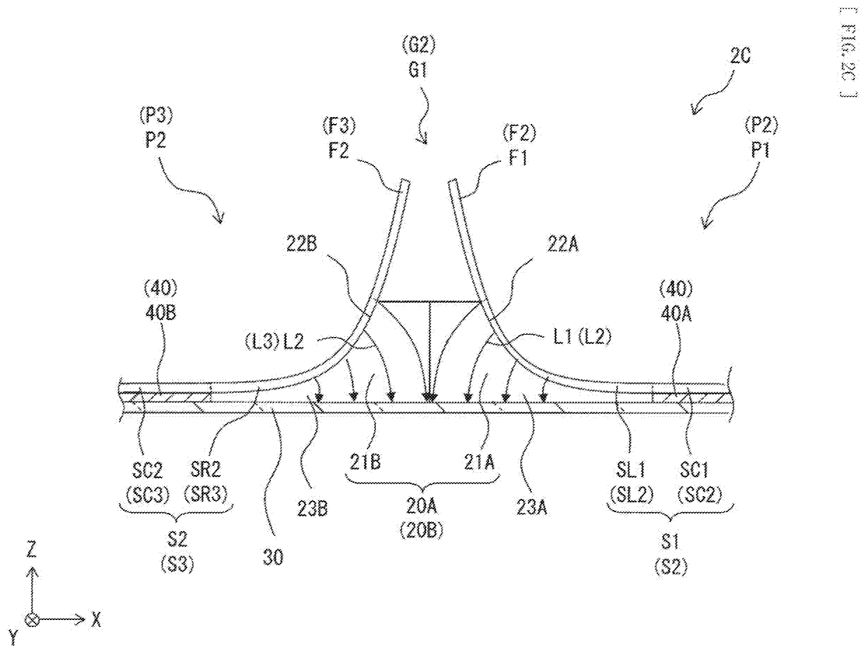

FIG. 2A is an enlarged cross-sectional view of a principal part of a display 2A according to a second embodiment of the present disclosure, and corresponds to FIG. 1C of the first embodiment described above.

As illustrated in FIG. 2A, the display 2A further includes an optical film 30 having flexibility that is disposed to entirely cover the coupled display surface SS. The coupled display surface SS is integrally formed by the middle regions SC of the plurality of display panels P and the first outgoing surface 23A and the second outgoing surface 23B of the FOP 20. As the optical film 30, for example, it is possible to use an anti-reflection (AR) film or a viewing angle diffusing film. Except for the above-described point, the display 2A has substantially the same configuration as the display 1 according to the above-described first embodiment.

In a case where the viewing angle diffusion film is used as the optical film 30, the optical film 30 functions to convert light distribution of the image light L outputted from the coupled display surface SS. Specifically, the optical film 30 functions to change a travel direction of the image light L while transmitting the image light L that directly enters from the middle regions SC of the display panels P or enters via the FOP 20, and functions to convert the light distribution of the image light L to achieve a uniform luminance distribution when viewed from a front direction, for example. The optical film 30 preferably has a refractive index lower than the refractive index of the core 261 of the optical fibers 26 (e.g., about 1.8) and higher than 1. One reason for this is that a transmission loss when the image light L outputted from the first outgoing surface 23A and the second outgoing surface 23B of the FOP 20 enters the optical film 30 is reduced and high transmission efficiency is secured. However, in a case where priority is given to expanding the viewing angle, the optical film 30 having a higher refractive index than the refractive index of the core 261 of the optical fibers 26 may be used.

### [Workings and Effects of Display 2]

The display 2A of the present embodiment achieves similar effects to those of the display 1 of the first embodiment as described above. That is, because the plurality of display panels P1 to P3 is coupled and integrated at the boundary portions G1 and G2, the large display surface is formed as a whole. In particular, because the FOPs 20A and 20B as the light guide members are arranged at the boundary portions G1 and G2, the pieces of image light L1 to L3 outputted from the plurality of display panels P1 to P3 are coupled to each other without gaps. In addition, the display 2A of the present embodiment provides the optical film 30 on a front surface of the FOP 20 provided on the plurality of display panels P and the boundary portions G1 and G2 therebetween. This results in reduction of difference in luminance and chromaticity between the image light L from the middle regions SC of the display section S and the image light L from the end regions SR and SL of the plurality of display panels P, and reduction of variation in image quality of the entire image displayed on the coupled display surface SS. Furthermore, the optical film 30 functions as a protective film that protects the coupled display surface SS from external force, making it possible to prevent the function of the display 2A from being damaged during transportation, installation, or after installation. In addition to the above, the optical film 30 has flexibility, which does not hinder the winding of the display 2A. Providing the optical film 30 makes it possible to improve mechanical strength of the entire display 2A, which prevents the wound display 2 from being crushed or bent, and makes it possible to maintain quality. Furthermore, providing the optical film 30 makes it possible to suppress occurrence of wrinkles and flexure in the middle regions SC of the display sections S, and makes it possible to expect better image display.

Note that it is possible to bond the first outgoing surface 23A and the second outgoing surface 23B of the FOP 20 to the optical film 30 by adhesion with an adhesive such as a transparent resin. Alternatively, the optical film 30 may be formed by applying a liquid on the coupled display surface SS.

### 3. MODIFICATION EXAMPLE OF SECOND EMBODIMENT

### [Configuration of Display 2B]

FIG. 2B is an enlarged cross-sectional view of a principal part of a display 2B as a first modification example of the above-described second embodiment, and corresponds to FIG. 2A of the above-described second embodiment.

As illustrated in FIG. 2B, the display 2B of the present modification example couples the display panels P only by the optical film 30 without disposing the FOP 20. Except for this point, the display 2B has substantially the same configuration as the display 2A according to the above-described second embodiment.

The display 2B of the present modification example also forms a large display surface as a whole because the plurality of display panels P1 to P3 is coupled and integrated by the optical film 30. In the display 2B, the end regions SL and SR of the display sections S are curved to cause the gap between the adjacent display sections S to be smaller. Therefore, the gaps between the pieces of image light L1 to L3 outputted from the display panels P1 to P3 are smaller than a case where the end regions SL and SR of the display sections S are not curved. Furthermore, because the display 2B has a configuration in which the FOPs 20A and 20B as the light guide members are not disposed at the boundary portions G1 and G2, the display 2B is advantageous in terms of an overall weight saving and a reduction in thickness as compared with the display 2A. However, because the display 2B does not have the FOP 20, it is preferable that the pieces of image light L outputted from the end regions SL and SR curved with respect to the flat middle regions SC be subjected to image processing to achieve an image having no distortion at a position of the coupled display surface SS along the optical film 30.

### [Configuration of Display 2C]

FIG. 2C is an enlarged cross-sectional view of a principal part of a display 2C as a second modification example of the above-described second embodiment, and corresponds to FIG. 2A of the above-described second embodiment.

As illustrated in FIG. 2C, the display 2C of the present modification example provides transparent support substrates 40 (40A and 40B) between the optical film 30 and the middle regions SC of the display sections S. The transparent support substrates 40 are so provided as to allow an end face of the substrate to contact end faces of the first light guide section 21A and the second light guide section 21B provided at the boundary portions G1 and G2. Except for this point, the display 2C has substantially the same configuration as the display 2A according to the above-described second embodiment.

Because the display 2C of the present modification example provides the transparent support substrates 40 on the display surfaces of the middle regions SC, it is possible to suppress occurrence of wrinkles and flexure in the middle regions SC of the display sections S in the manufacturing stage or at the time of installation, and makes it possible to expect better image display. Furthermore, it is also possible to protect the end of the FOP 20. It is possible to form the transparent support substrates 40 from a transparent resin having flexibility. In that case, it is possible to wind the display 1 and secure transportability. Note that the transparent support substrates 40 may be formed of glass plates.

### 4. THE OTHER MODIFICATION EXAMPLES

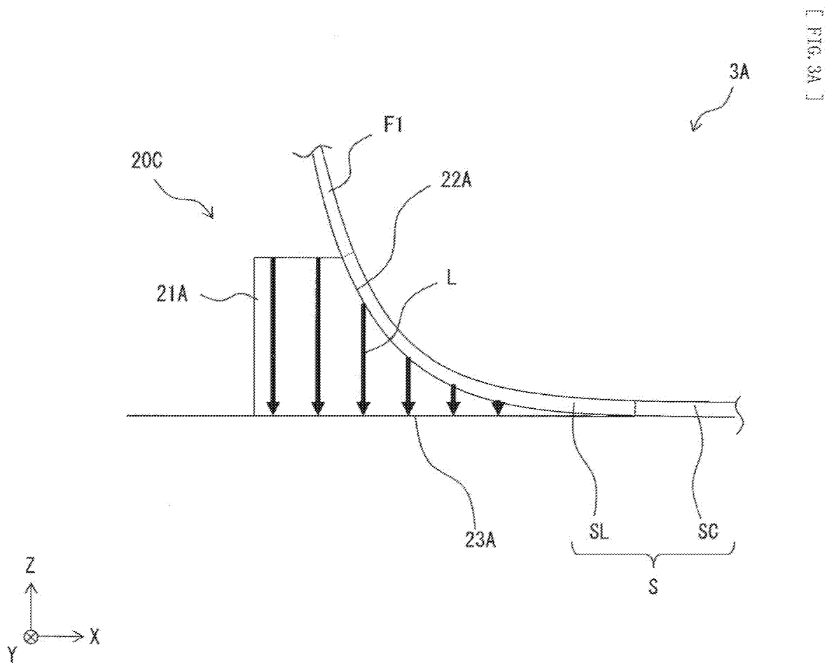

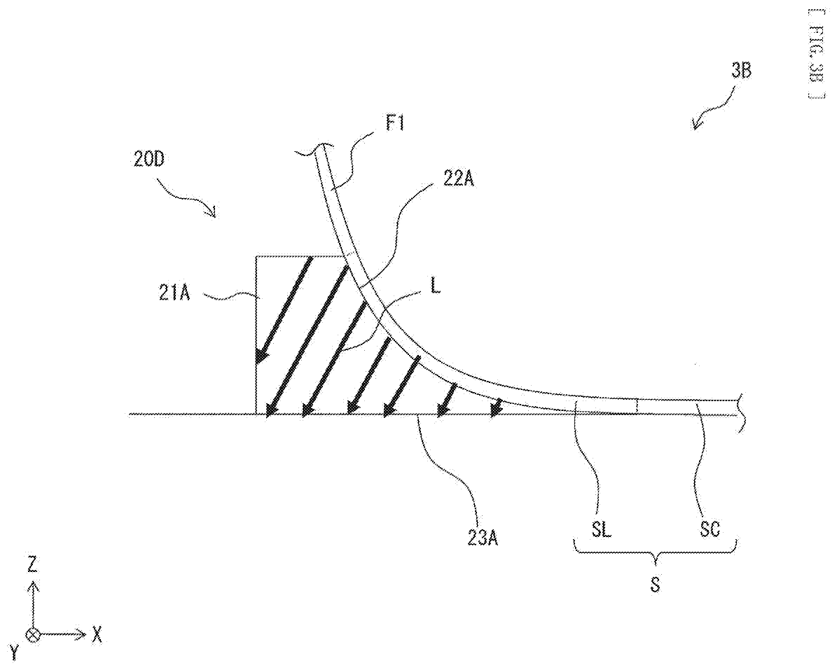

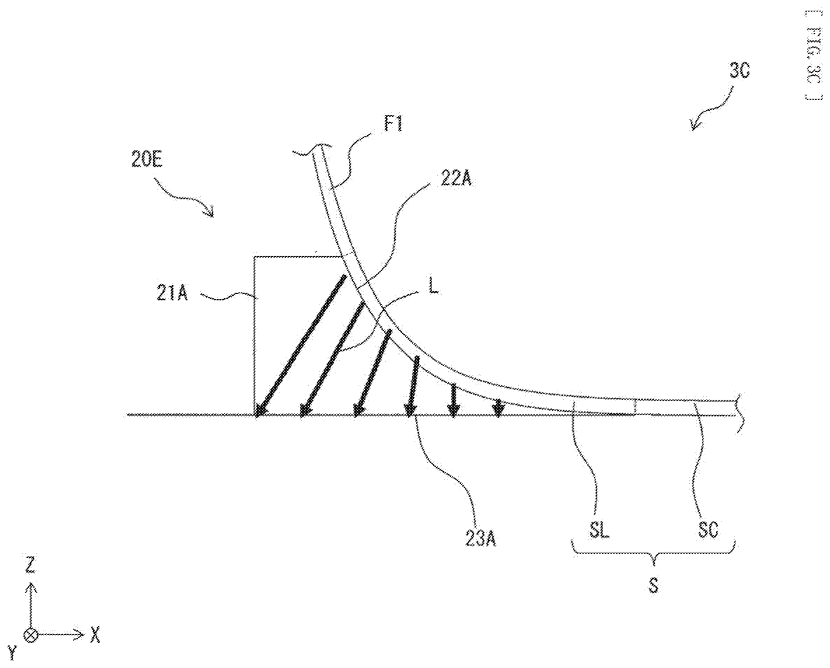

As described above, the present disclosure has been described with reference to some embodiments and modification examples, but the present disclosure is not limited to the above-described embodiments and the like, and various modifications are possible. For example, the FOP 20 as the light guide member in the display 1 according to the above-described first embodiment has the optical fibers 26 including the core 261 whose optical axis is curved, but the present disclosure is not limited thereto. For example, the display may include an FOP 20C in which the image light L travels straight in a direction orthogonal to the coupled display surface SS as in a display 3A illustrated in FIG. 3A. Note that the FOP 20C includes the first light guide section 21A and the second light guide section 21B, but FIG. 3A illustrates only the first light guide section 21A. Alternatively, the display may include an FOP 20D in which the image light L travels straight in an oblique direction with respect to the coupled display surface SS as in a display 3B illustrated in FIG. 3B. The FOP 20D includes the first light guide section 21A and the second light guide section 21B, but FIG. 3B illustrates only the first light guide section 21A.

Furthermore, the light guide member of the present disclosure may enlarge and propagate the image light L that has entered the entering surfaces (the first entering surface 22A and the second entering surface 22B) before reaching the outgoing surfaces (the first outgoing surface 23A and the second outgoing surface 23B), and may output the enlarged image light L from the outgoing surfaces, for example, as in an FOP 20E as the light guide member illustrated in FIG. 3C. Using the FOP 20C having such an enlargement function makes it possible to reduce sizes of the curved end regions SL and SR of the display sections S, and advantageously allows for a reduction in thickness at the boundary portions G1 and G2 as well. The FOP 20E includes the first light guide section 21A and the second light guide section 21B, but FIG. 3C illustrates only the first light guide section 21A.

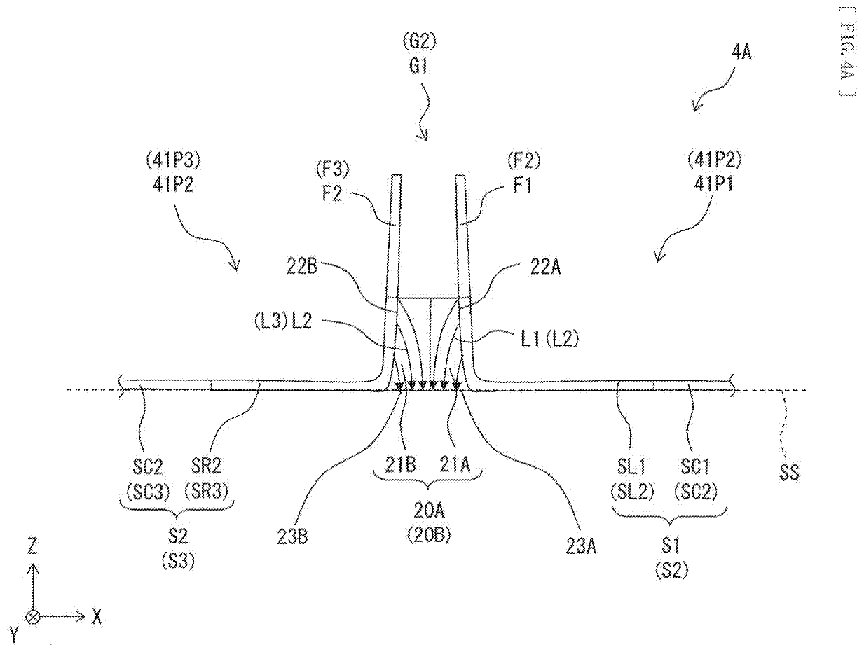

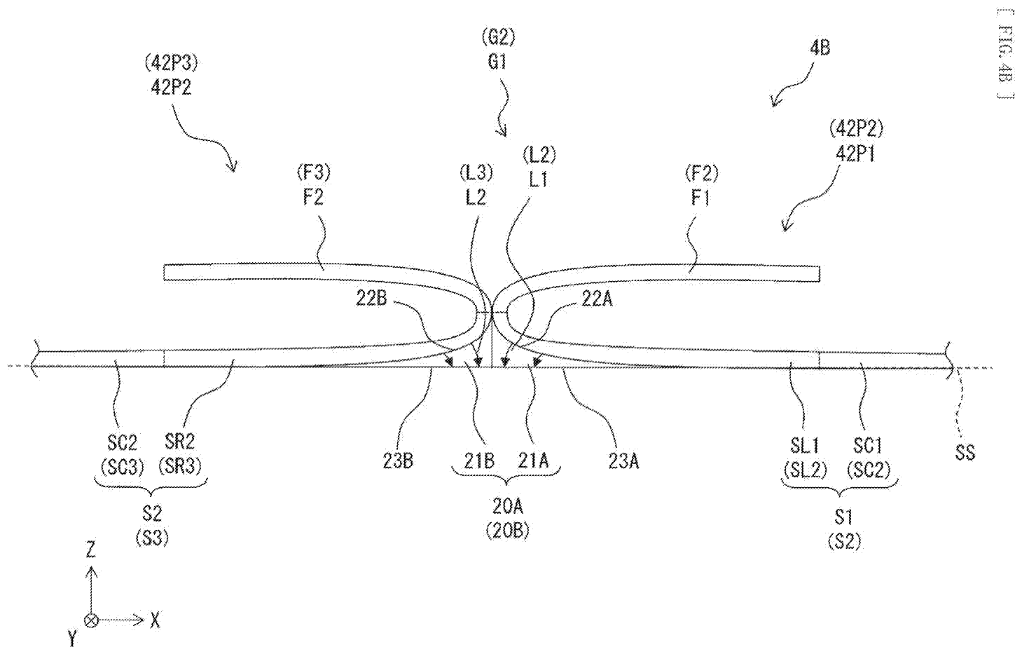

Furthermore, in the above-described embodiments, etc., the end regions SL and SR of the display sections S are gradually curved to have an angle within a range of 0° to less than 90° with respect to a direction in which the middle regions SC extends, but the present disclosure is not limited thereto. For example, as in a display 4A illustrated in FIG. 4A, display panels 41P (41P1 to 41P3) that are bent perpendicularly to the coupled display surface SS may be provided at the boundary position between the middle region SC and the end region SL and at the boundary position between the middle region SC and the end region SR. Thus, widths of the boundary portions G1 and G2 of the display 4A are reduced as compared with the case where the end regions SL and SR are gradually curved as in the display 1 and the like of the above-described embodiment, etc., which is advantageous for compactness. Alternatively, for example, the display panels 42P (42P1 to 42P3) may be provided as in a display 4B illustrated in FIG. 4B. The display panel 42P1 is folded at the boundary position between a peripheral part F1 and the end region SL1 to cause the peripheral part F1 to overlap the end region SL1 in a thickness direction. The display panel 42P2 is folded at the boundary position between a peripheral part F2 and the end region SR2 and at the boundary position between the peripheral part F2 and the end region SL2 to cause the peripheral part F2 to overlap the end region SR2 and the end region SL2 in the thickness direction. Furthermore, the display panel 42P3 is folded at the boundary position between a peripheral part F3 and the end region SR3 to cause the peripheral part F3 to overlap the end region SR3 in a thickness direction. Thus, the display 4B is advantageous for compactness as compared with the case where the end regions SL and SR are gradually curved as in the display 1 and the like of the above-described embodiment, etc. One reason for this is that in the display 4B, the widths (dimensions in the X-axis direction) of the boundary portions G1 and G2 are reduced and a thickness (dimension in the Z-axis direction) near the boundary portions G1 and G2 is reduced as compared with the display 1 and the like. Moreover, as compared with the display 1 or the display 4B, it is possible to further shorten a distance from the end regions SL and SR to the coupled display surface SS, making it possible to ease degrading in luminance at the boundary portions G1 and G2.

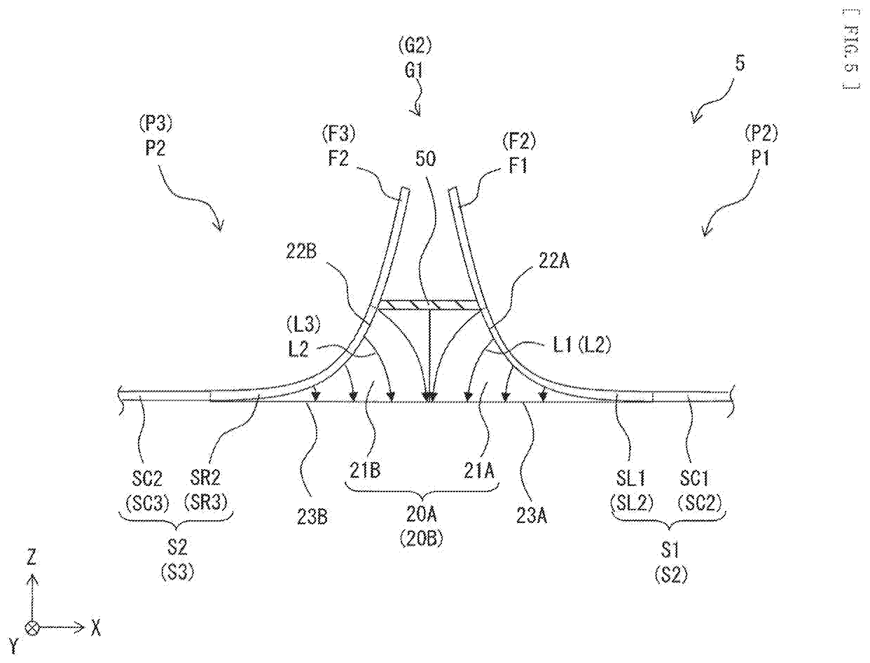

Furthermore, the display of the present disclosure may provide a light shielding film 50 that covers a surface opposite to the first outgoing surface 23A and the second outgoing surface 23B of the FOP 20 as in a display 5 illustrated in FIG. 5, for example. Providing the light shielding film 50 as described above allows for elimination of unnecessary external light leaking to the coupled display surface SS from the gap between the first light guide section 21A and the second light guide section 21B, for example.

Furthermore, although the above-described embodiments, etc., illustrate the cases where the shape and size of the plurality of display panels P and the shape and size of the plurality of FOPs 20 are substantially the same, the present disclosure is not limited thereto. In the present disclosure, some or all of the shapes and sizes of the plurality of display members may be different, and some or all of the shapes and sizes of the plurality of light guide members may be different.

Moreover, it is to be noted that effects described herein are merely exemplified. Effects of the present disclosure are not limited to the effects described herein and may include other effects than the effects described herein. Furthermore, the present technology may include the following configurations.

(1)

A display including:

a first display member including a first display section, the first display section having a first middle region and a curved first end region and outputting first image light;

a second display member including a second display section, the second display section having a second middle region and a curved second end region and outputting second image light, the second display section being adjacent to the first display section via a gap; and

a light guide member that is provided on the gap and has
a first entering surface where the first image light from the first end region enters,
a first outgoing surface that outputs the first image light from the first entering surface,
a second entering surface where the second image light from the second end region enters, and
a second outgoing surface that outputs the second image light from the second entering surface.
   (2)

The display according to (1), in which the light guide member includes:

a first light guide section including bundled and integrated first optical fibers, the first optical fibers each having a first core and a first cladding, the first core guiding the first image light from the first entering surface to the first outgoing surface, the first cladding surrounding the first core; and

a second light guide section including bundled and integrated second optical fibers, the second optical fibers each having a second core and a second cladding, the second core guiding the second image light from the second entering surface to the second outgoing surface, the second cladding surrounding the second core.

(3)

The display according to (1) or (2), in which the light guide member

enlarges the first image light that has entered the first entering surface and outputs the enlarged first image light from the first outgoing surface, and

enlarges the second image light that has entered the second entering surface and outputs the enlarged second image light from the second outgoing surface.

(4)

The display according to any one of (1) to (3), in which the first display section and the second display section include flexible displays.

(5)

The display according to any one of (1) to (4), in which the first middle region of the first display section, the second middle region of the second display section, and the first outgoing surface and the second outgoing surface of the light guide member integrally form a coupled display surface.

(6)

The display according to (5), further including an optical film that covers the coupled display surface.

(7)

The display according to any one of (1) to (6), further including at least one of a first transparent plate that covers the first middle region of the first display section or a second transparent plate that covers the second middle region of the second display section.

(8)

A display including:

a first display member including a first display section, the first display section having a first middle region and a curved first end region and outputting first image light;

a second display member including a second display section, the second display section having a second middle region and a curved second end region and outputting second image light, the second display section being adjacent to the first display section via a gap; and

an optical film that covers, over the gap, both the first middle region of the first display section and the second middle region of the second display section.

The present application claims the benefit of Japanese Priority Patent Application JP2018-63869 filed with the Japan Patent Office on Mar. 29, 2018, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A display comprising:
a first display member including a first display section, the first display section having a first middle region and a curved first end region and outputting first image light;
a second display member including a second display section, the second display section having a second middle region and a curved second end region and outputting second image light, the second display section being adjacent to the first display section via a gap; and
a light guide member that is provided on the gap and has
a first entering surface where the first image light from the first end region enters,
a first outgoing surface that outputs the first image light from the first entering surface,
a second entering surface where the second image light from the second end region enters, and
a second outgoing surface that outputs the second image light from the second entering surface.

2. The display according to claim 1, wherein the light guide member includes:
a first light guide section including bundled and integrated first optical fibers, the first optical fibers each having a first core and a first cladding, the first core guiding the first image light from the first entering surface to the first outgoing surface, the first cladding surrounding the first core; and
a second light guide section including bundled and integrated second optical fibers, the second optical fibers each having a second core and a second cladding, the second core guiding the second image light from the second entering surface to the second outgoing surface, the second cladding surrounding the second core.

3. The display according to claim 1, wherein the light guide member
enlarges the first image light that has entered the first entering surface and outputs the enlarged first image light from the first outgoing surface, and
enlarges the second image light that has entered the second entering surface and outputs the enlarged second image light from the second outgoing surface.

4. The display according to claim 1, wherein the first display section and the second display section comprise flexible displays.

5. The display according to claim 1, wherein the first middle region of the first display section, the second middle region of the second display section, and the first outgoing surface and the second outgoing surface of the light guide member integrally form a coupled display surface.

6. The display according to claim 5, further comprising an optical film that covers the coupled display surface.

7. The display according to claim 1, further comprising at least one of a first transparent plate that covers the first middle region of the first display section or a second transparent plate that covers the second middle region of the second display section.

8. A display comprising:
a first display member including a first display section, the first display section having a first middle region and a curved first end region and outputting first image light;
a second display member including a second display section, the second display section having a second middle region and a curved second end region and outputting second image light, the second display section being adjacent to the first display section via a gap; and
an optical film that covers, over the gap, both the first middle region of the first display section and the second middle region of the second display section.
